(19) United States
(12) Patent Application Publication
(10) Pub. No.: US 2017/0012136 A1
(43) Pub. Date: Jan. 12, 2017

(54) SEMICONDUCTOR DEVICE AND MANUFACTURING METHOD THEREOF

(71) Applicants: Toyota Jidosha Kabushiki Kaisha, Toyota-shi Aichi-ken (JP); Denso Corporation, Kariya-shi Aichi-ken (JP)

(72) Inventors: Yosuke Maegawa, Miyoshi-shi (JP); Shinichiro Miyahara, Kariya-shi Aichi-ken (JP); Narumasa Soejima, Nagakute-shi (JP)

(21) Appl. No.: 15/201,938

(22) Filed: Jul. 5, 2016

(30) Foreign Application Priority Data
Jul. 7, 2015 (JP) 2015-136478

(51) Int. Cl. H01L 29/788; H01L 29/78; H01L 29/16; H01L 29/40; H01L 29/66; H01L 21/265; H01L 29/739; H01L 29/06; H01L 29/423; H01L 29/10

(52) U.S. Cl. CPC H01L 29/7889; H01L 29/4236; H01L 29/7813; H01L 29/1608; H01L 29/1095; H01L 29/66068; H01L 21/265; H01L 29/7397; H01L 29/7811; H01L 29/0623; H01L 29/404; H01L 29/407

(57) ABSTRACT

A terminal structure includes: a first trench extending along a depth direction from an upper surface of a semiconductor substrate; a plurality of second trenches, each of which extends along the depth direction from a bottom surface of the first trench and which are arranged at intervals in a direction away from an element portion; a plurality of first floating regions having a floating potential, each of which is exposed at the bottom surface of the first trench, is disposed between the second trenches, and forms a PN-junction with a surrounding region thereof; and a plurality of second floating regions having a floating potential, each of which is exposed at a bottom surface of the second trench and forms a PN-junction with a surrounding region thereof. The plurality of second floating regions is arranged to be separated from each other in the direction away from the element portion.

### CROSS-REFERENCE TO RELATED APPLICATION

This application claims priority to Japanese Patent Application No. 2015-136478 filed on Jul. 7, 2015, the entire contents of which are hereby incorporated by reference into the present application.

### TECHNICAL FIELD

A technique disclosed herein relates to a semiconductor device and a manufacturing method thereof.

### DESCRIPTION OF RELATED ART

Japanese Patent Application Publication No. 2008-135522 discloses a semiconductor device that includes a semiconductor substrate partitioned into an element portion provided with a switching structure and a peripheral portion provided with a terminal structure. In this semiconductor device, a plurality of trenches is formed in the peripheral portion of the semiconductor substrate. The plurality of trenches extends along a depth direction from an upper surface of the semiconductor substrate, and is arranged at intervals in a direction away from the element portion. Furthermore, in this semiconductor device, a p-type floating region that has a floating potential is formed at a bottom surface of each of the plurality of trenches. The plurality of trenches and the plurality of floating regions form the terminal structure.

When the switching structure in the element portion is turned off, a depletion layer spreads from the element portion toward the peripheral portion. At this time, the plurality of floating regions that form the terminal structure can allow the depletion layer that extends from the element portion to further extend toward an outside, to promote depletion in the peripheral portion. This improves the withstand voltage of the semiconductor device.

### SUMMARY

To lower the on-resistance (or the on-voltage) of the semiconductor device of this type, it is desirable to increase a substrate concentration of the semiconductor substrate. However, if the substrate concentration of the semiconductor substrate is increased, extension of the depletion layer is restrained, and the withstand voltage is decreased. To restrain such a decrease in withstand voltage, it is preferable to narrow a pitch width of the trenches in the terminal structure and narrow the intervals between the floating regions to thereby promote extension of the depletion layer. However, to form trenches having a narrow pitch width, a high-accuracy processing technology is needed, causing a problem of difficulty in manufacturing thereof.

The present specification has a main object of providing a semiconductor device that includes a terminal structure that has an easy processability and a high withstand voltage.

In one aspect of the present teachings, a semiconductor device comprises a semiconductor substrate partitioned into an element portion provided with a switching structure and a peripheral portion provided with a terminal structure. The terminal structure includes a first trench, a plurality of second trenches, a plurality of first floating regions and a plurality of second floating regions. The first trench extends along a depth direction from one of main surfaces of the semiconductor substrate. Each of the plurality of second trenches extends along the depth direction from a bottom surface of the first trench, and the second trenches are arranged at intervals in a direction away from the element portion. The plurality of first floating regions has a floating potential. Each of the first floating regions is disposed at the bottom surface of the first trench, is arranged between the second trenches, and forms a PN-junction with a surrounding region thereof. The plurality of second floating regions has a floating potential. Each of the second floating regions is disposed at a bottom surface of the second trench and forms a PN-junction with a surrounding region thereof. Each of second floating regions is arranged to be separated from each other in the direction away from the element portion.

In the above-described semiconductor device, the plurality of first floating regions and the plurality of second floating regions are disposed in the peripheral portion of the semiconductor substrate. The plurality of first floating regions is arranged at a relatively shallow position in the semiconductor substrate, while the plurality of second floating regions is arranged at a relatively deep position in the semiconductor substrate, resulting in that the plurality of first floating regions and the plurality of second floating regions are arranged at different depths. The first floating regions and the second floating regions are alternately arranged in the direction away from the element portion, in the peripheral portion of the semiconductor substrate. In other words, each of the first floating regions is disposed between the second floating regions. As such, in the above-described semiconductor device, the plurality of first floating regions and the plurality of second floating regions are arranged at the different depths, and hence in the peripheral portion of the semiconductor substrate, the floating regions can be arranged at small intervals in the direction away from the element portion. In other words, even in a case where a small pitch width is not achieved between the second trenches, the floating regions can exist at a high density in the direction away from the element portion, in the peripheral portion of the semiconductor substrate. The above-described semiconductor device can include the terminal structure that has an easy processability and a high withstand voltage.

In one aspect of the present teachings, a manufacturing method of a semiconductor device comprising a semiconductor substrate partitioned into an element portion provided with a switching structure and a peripheral portion provided with a terminal structure is disclosed. The method comprises preparing the semiconductor substrate, forming a first trench, forming a plurality of second trenches, forming a plurality of first floating regions and forming a plurality of second floating regions. In the forming of the first trench, the first trench extending along a depth direction from one of main surfaces of the semiconductor substrate at the peripheral portion is formed. In the forming of the plurality of second trenches, each of second trenches extending along the depth direction from a bottom surface of the first trench is formed such that second trenches are arranged at intervals in a direction away from the element portion. In the forming of the plurality of first floating regions, the plurality of first floating regions having a floating potential is formed such that each of first floating regions is disposed at the bottom surface of the first trench, is arranged between the second trenches, and forms PN-junction with a surrounding region thereof. In the forming of the plurality of second floating regions, the plurality of second floating regions having a floating potential is formed such that each of the second floating regions is disposed at a bottom surface of the second trench and forms a PN-junction with a surrounding region thereof. Each of second floating regions is arranged to be separated from each other in the direction away from the element portion.

In the above-described manufacturing method, after the first trench is formed, the plurality of second trenches, each of which extends along the depth direction from the bottom surface of the first trench, is formed. The bottom surface of the first trench is thereby divided into a plurality of bottom surface sections, and hence the first floating region can be formed at each of the plurality of bottom surface sections thus obtained by dividing the bottom surface. Moreover, the second floating region is formed at each of the bottom surfaces of the plurality of second trenches. As such, in the above-described manufacturing method, by forming the plurality of second trenches, each of which extends along the depth direction from the bottom surface of the first trench, it is possible to easily manufacture a structure in which the plurality of first floating regions and the plurality of second floating regions are arranged at different depths, and each of the first floating regions is disposed between the second floating regions.

### BRIEF DESCRIPTION OF DRAWINGS

FIG. 1 schematically shows a cross-sectional view of a main part of a semiconductor device in Embodiment 1;

FIG. 2A schematically shows a cross-sectional view of a main part of a manufacturing process of the semiconductor device in Embodiment 1;

FIG. 2B schematically shows a cross-sectional view of a main part of the manufacturing process of the semiconductor device in Embodiment 1;

FIG. 2C schematically shows a cross-sectional view of a main part of the manufacturing process of the semiconductor device in Embodiment 1;

FIG. 2D schematically shows a cross-sectional view of a main part of the manufacturing process of the semiconductor device in Embodiment 1;

FIG. 2E schematically shows a cross-sectional view of a main part of the manufacturing process of the semiconductor device in Embodiment 1;

FIG. 2F schematically shows a cross-sectional view of a main part of the manufacturing process of the semiconductor device in Embodiment 1;

FIG. 2G schematically shows a cross-sectional view of a main part of the manufacturing process of the semiconductor device in Embodiment 1;

FIG. 2H schematically shows a cross-sectional view of a main part of the manufacturing process of the semiconductor device in Embodiment 1;

FIG. 3 schematically shows a cross-sectional view of a main part of a semiconductor device in a variation of Embodiment 1;

FIG. 4 schematically shows a cross-sectional view of a main part of a semiconductor device in Embodiment 2;

FIG. 5A schematically shows a cross-sectional view of a main part of a manufacturing process of the semiconductor device in Embodiment 2;

FIG. 5B schematically shows a cross-sectional view of a main part of the manufacturing process of the semiconductor device in Embodiment 2;

FIG. 5C schematically shows a cross-sectional view of a main part of the manufacturing process of the semiconductor device in Embodiment 2;

FIG. 5D schematically shows a cross-sectional view of a main part of the manufacturing process of the semiconductor device in Embodiment 2;

FIG. 5E schematically shows a cross-sectional view of a main part of the manufacturing process of the semiconductor device in Embodiment 2;

FIG. 5F schematically shows a cross-sectional view of a main part of the manufacturing process of the semiconductor device in Embodiment 2; and

FIG. 6 schematically shows a cross-sectional view of a main part of a semiconductor device in a variation of Embodiment 2.

### DETAILED DESCRIPTION

### Embodiment 1

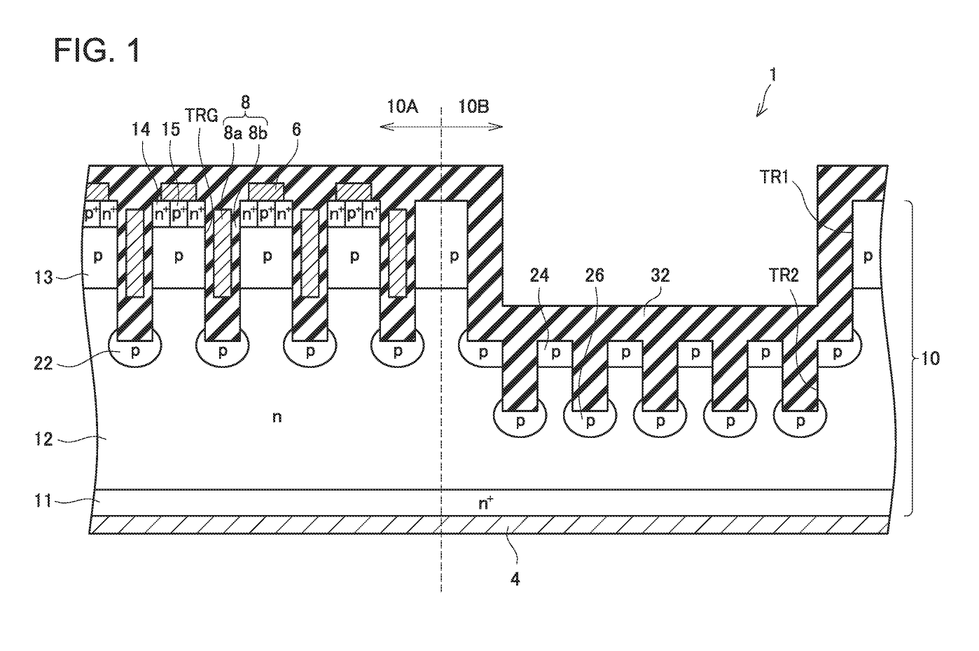

As shown in FIG. 1, a semiconductor device 1 includes a semiconductor substrate 10 made of silicon carbide (SiC), a drain electrode 4, a source electrode 6, a plurality of trench gates 8, and a protection film 32. The semiconductor substrate 10 is partitioned into an element portion 10A provided with a MOS structure and a peripheral portion 10B provided with a terminal structure. In a view along a direction orthogonal to an upper surface of the semiconductor substrate 10 (hereinafter referred to as “in a planar view”), the peripheral portion 10B is arranged to encircle the perimeter of the element portion 10A. The drain electrode 4 is in contact with a lower surface of the semiconductor substrate 10 in a range at both of the element portion 10A and the peripheral portion 10B. The source electrode 6 is in contact with the upper surface of the semiconductor substrate 10 in a range at the element portion 10A. Each of the plurality of trench gates 8 is disposed in a gate trench TRG formed in an upper-layer portion of the semiconductor substrate 10 in a range at the element portion 10A. In a planar view of the semiconductor substrate 10, the plurality of trench gates 8 have a stripe-like or lattice-like layout, for example. The protection film 32 covers the upper surface of the semiconductor substrate 10 in a range at both of the element portion 10A and the peripheral portion 10B. As described in a manufacturing method mentioned below, the protection film 32 may be formed simultaneously with a gate insulating film 8b of the trench gate 8, or may be formed separately from the gate insulating film 8b of the trench gate 8.

The semiconductor substrate 10 has an n⁺-type drain region 11, an n-type drift region 12, a p-type body region 13, a plurality of n⁺-type source regions 14, a plurality of p⁺-type body contact regions 15, a plurality of p-type gate floating regions 22, a plurality of p-type first floating regions 24, and a plurality of p-type second floating regions 26.

The drain region 11 is disposed in a lower-layer portion of the semiconductor substrate 10 in a range at both of the element portion 10A and the peripheral portion 10B. The drain region 11 is exposed at the lower surface of the semiconductor substrate 10, and is in ohmic contact with the drain electrode 4.

The drift region 12 is disposed in the semiconductor substrate 10 in a range at both of the element portion 10A and the peripheral portion 10B, and is in contact with the drain region 11 and the body region 13. The drift region 12 is arranged between the drain region 11 and the body region 13, and separates the drain region 11 and the body region 13.

The body region 13 is disposed in the upper-layer portion of the semiconductor substrate 10 in a range at the element portion 10A, and is in contact with the drift region 12, the source regions 14, and the body contact regions 15. The body region 13 is arranged between the drift region 12 and the source region 14, and separates the drift region 12 and the source region 14.

Each of the source regions 14 is disposed in the upper-layer portion of the semiconductor substrate 10 in a range at the element portion 10A, and is in contact with the body region 13 and corresponding one of the body contact regions 15. The source region 14 is exposed at the upper surface of the semiconductor substrate 10, and is in ohmic contact with the source electrode 6.

Each of the body contact regions 15 is disposed in the upper-layer portion of the semiconductor substrate 10 in a range at the element portion 10A, and is in contact with the body region 13 and the source region 14. The body contact region 15 is exposed at the upper surface of the semiconductor substrate 10, and is in ohmic contact with the source electrode 6.

Each of the gate floating regions 22 is disposed at a bottom surface of the corresponding gate trench TRG, is surrounded by the drift region 12, and forms a PN-junction with the drift region 12. Accordingly, the gate floating region 22 has a floating potential. The plurality of gate floating regions 22 is arranged to be separated from each other.

Each a the trench gate 8 is disposed in the gate trench TRG that extends along a depth direction from the upper surface of the semiconductor substrate 10, and has a gate electrode 8a and the gate insulating film 8b that covers the gate electrode 8a. Each of the trench gate 8 penetrates the corresponding source regions 14 and the body region 13 and reaches the drift region 12. The gate electrode 8a of the trench gate 8 faces the body region 13, Which separates the drift region 12 and the source region 14, via the gate insulating film 8b. The body region 13 that this gate electrode 8a faces is a region where a channel is to be formed. As such, the element portion 10A of the semiconductor substrate 10 is provided with the MOS structure comprising the trench gate 8, the drift region 12, the body region 13, and the source region 14.

In the peripheral portion 10B of the semiconductor substrate 10, a first trench TR1 and a plurality of second trenches TR2 are formed. The first trench TR1 extends along the depth direction from the upper surface of the semiconductor substrate 10 (i.e., the upward and downward directions on a paper surface of the drawing), and in this example, is formed to be deeper than the body region 13. In a planar view of the semiconductor substrate 10, the first trench TR1 is formed to encircle the perimeter of the element portion 10A. Each of the plurality of second trenches TR2 extends along the depth direction from a bottom surface of the first trench TR1, and is formed to have a bottom surface located in the drift region 12. The plurality of second trenches TR2 is arranged at intervals in a direction away from the element portion 10A (i.e., left and right directions on the paper surface of the drawing). In this example, the plurality of second trenches TR2 has equal depths, and is arranged at equal intervals in the direction away from the element portion 10A. In a planar view of the semiconductor substrate 10, the plurality of second trenches TR2 is formed to encircle the perimeter of the element portion 10A. Notably, in this example, a p-type floating region is disposed in the upper-layer portion of the semiconductor substrate 10 closer to a peripheral edge with respect to the first trench TR1, but such a p-type region may not be disposed. Moreover, the first trench TR1 may be formed to reach a chip end.

Each of the first floating regions 24 is disposed at the bottom surface of the first trench TR1, is arranged between the second trenches TR2, is surrounded by the drift region 12, and forms a PN-junction with the drift region 12. Due to this, the first floating region 24 has a floating potential. The first floating regions 24 and the second floating regions 26 are arranged to be separated from each other in the depth direction.

Each of the second floating regions 26 is disposed at the bottom surface of the second trench TR2, is surrounded by the drift region 12, and forms a PN-junction with the drift region 12. Due to this, the second floating region 26 has a floating potential. The plurality of second floating regions 26 is arranged to be separated from each other in the direction away from the element portion 10A. Moreover, the second floating region 26 has a spreading form due to thermal diffusion, and is formed to protrude from a side surface of the second trench TR2, in a planar view of the semiconductor substrate 10. Accordingly, a part of each of the plurality of second floating regions 26 is arranged to overlap the first floating region 24, in a planar view of the semiconductor substrate 10.

As such, the peripheral portion 10B of the semiconductor substrate 10 is provided with the terminal structure comprising the first trench TR1, the plurality of second trenches TR2, the plurality of first floating regions 24, and the plurality of second floating regions 26.

Next, an operation of the semiconductor device 1 will be described. When a positive voltage is applied to the drain electrode 4, a ground voltage is applied to the source electrode 6, and a positive voltage is applied to the gate electrode 8a, a channel is formed in the body region 13 that the gate electrode 8a faces, and electrons flow from the source electrode 6 toward the drain electrode 4 through the source region 14, the channel, the drift region 12, and the drain region 11. The semiconductor device 1 is thereby turned on.

When the voltage applied to the gate electrode 8a is switched to a pound voltage, the channel disappears, and the semiconductor device 1 is turned off. When the semiconductor device 1 is turned off, a depletion layer spreads in the element portion 10A, from the PN-junction between the drift region 12 and the body region 13 toward an inside of the drift region 12. When the depletion layer reaches the gate floating regions 22 in the element portion 10A, the depletion layer also spreads from the gate floating regions 22 toward the inside of the drift region 12. The depletion layer extends in the element portion 10A as such, to thereby improve a withstand voltage of the element portion 10A.

Moreover, the depletion layer formed in the element portion 10A also spreads toward the peripheral portion 10B. The depletion layer that spreads from the element portion 10A can alternately reach the first floating regions 24 and the second floating regions 26 in the peripheral portion 10B, in the direction away from the element portion 10A, to thereby spread in the peripheral portion 10B in a wide range. In particular, a part of each of the plurality of second floating regions 26 is arranged to overlap the first floating region 24, in a planar view of the semiconductor substrate 10. Accordingly, the depletion layer that spreads in the peripheral portion 10B can alternately reach the first floating regions 24 and the second floating regions 26 in a favorable manner. The depletion layer extends in the peripheral portion 10B as such, to thereby improve the withstand voltage of the peripheral portion 10B.

In the peripheral portion 10B of the semiconductor device 1, the plurality of first floating regions 24 is arranged at a relatively shallow position in the semiconductor substrate 10, while the plurality of second floating regions 26 is arranged at a relatively deep position in the semiconductor substrate 10, resulting in that the plurality of first floating regions 24 and the plurality of second floating regions 26 are arranged at different depths. The first floating regions 24 and the second floating regions 26 are alternately arranged in the direction away from the element portion 10A, in the peripheral portion 10B of the semiconductor substrate 10. In other words, each of the first floating regions 24 is disposed between the second floating regions 26. As such, in the semiconductor device 1, the plurality of first floating regions 24 and the plurality of second floating regions 26 are arranged at different depths, and hence in the peripheral portion 10B of the semiconductor substrate 10, the floating regions 24 and 26 are arranged at small intervals in the direction away from the element portion 10A. This allows the depletion layer to spread in the peripheral portion 10B in a wide range, even in a case where the drift region 12 has a high impurity concentration, or other cases.

As described above, in the semiconductor device 1, the floating regions 24 and 26 are arranged at a high density in the peripheral portion 10B, and hence extension of the depletion layer can be promoted even in the case where the drift region 12 has a high impurity concentration, or other cases. In other words, in the semiconductor device 1, the depletion layer can favorably be extended in the peripheral portion 10B, even if the intervals between the second floating regions 26 are large. As described in the manufacturing method mentioned below, an ion implantation technology is utilized to form the second floating regions 26 at the bottom surface of the second trenches TR2. Each of the second trench TR2 is formed by initially forming the first trench TR1, and then utilizing an anisotropic etching technology to perform etching from the bottom surface of the first trench TR1. In other words, in the semiconductor device 1, the depletion layer can favorably be extended in the peripheral portion 10B, even if the second trenches TR2 have a large pitch width. Accordingly, the semiconductor device 1 can acquire characteristics including an easy processability, a high withstand voltage, and a low on resistance.

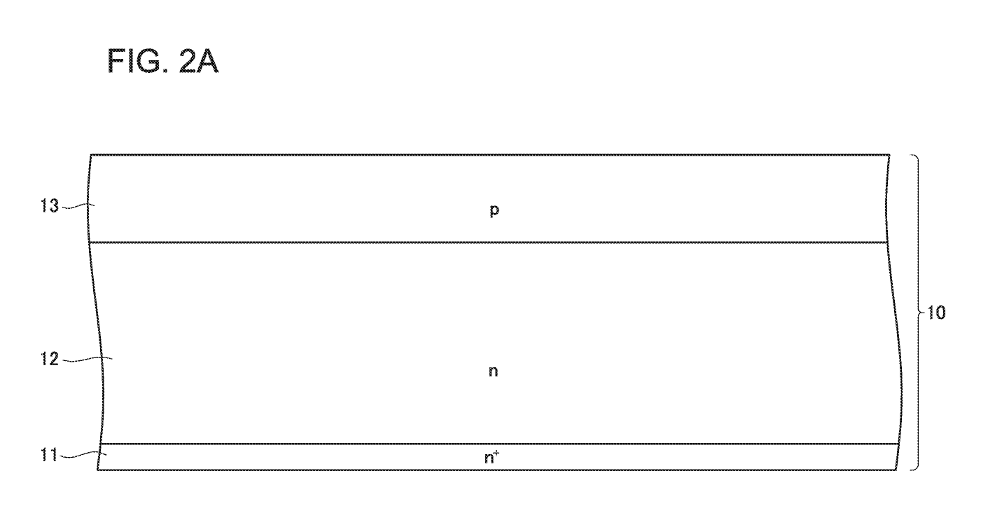

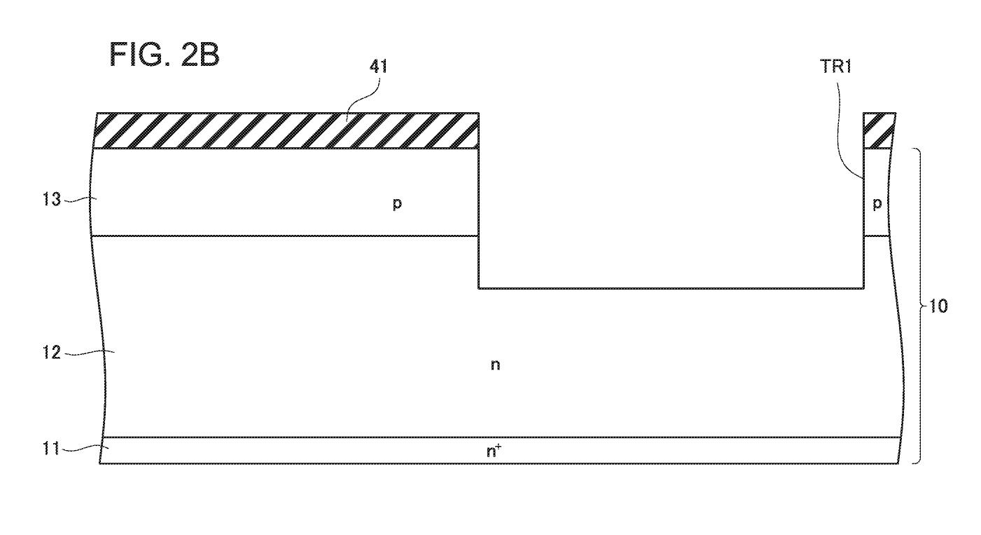

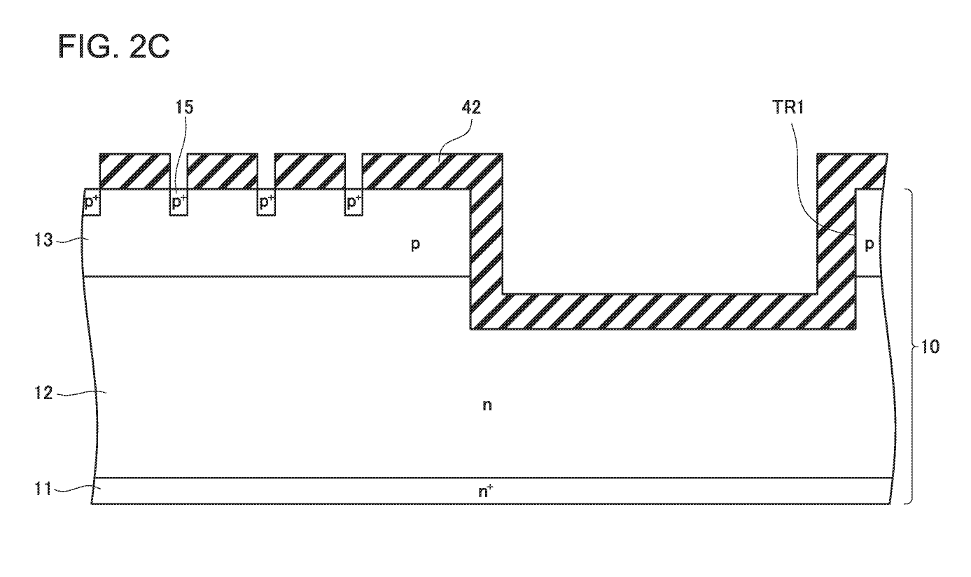

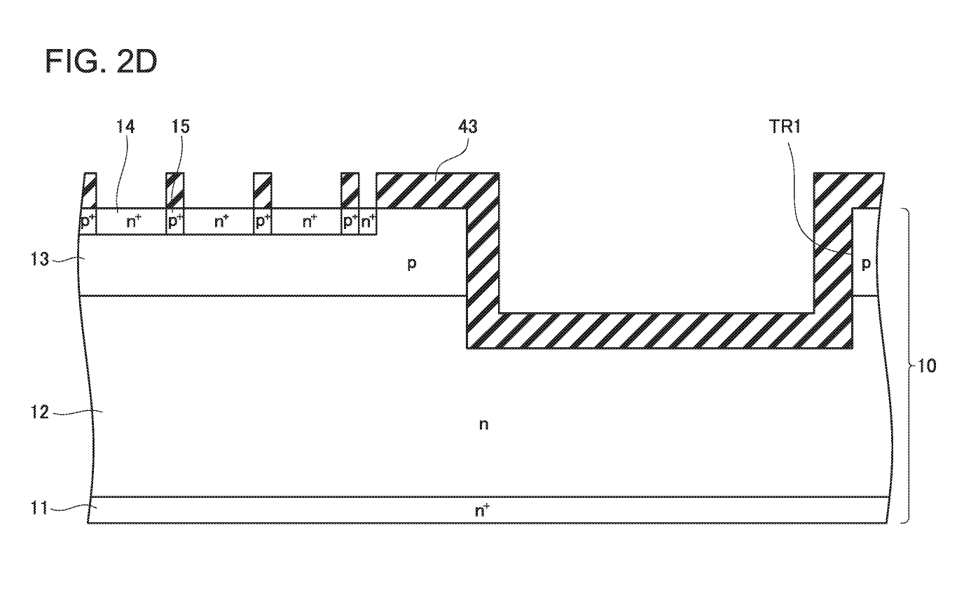

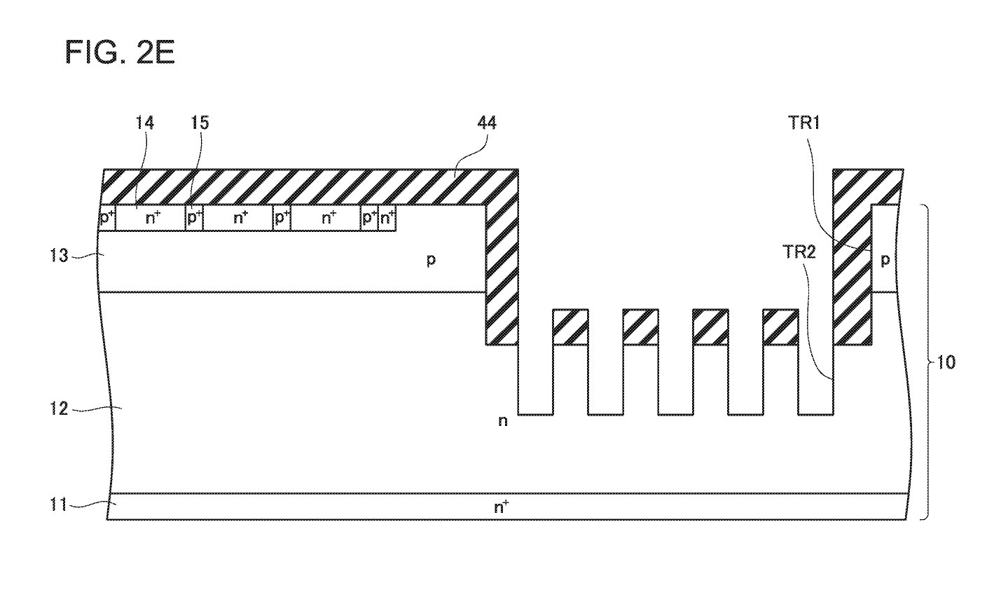

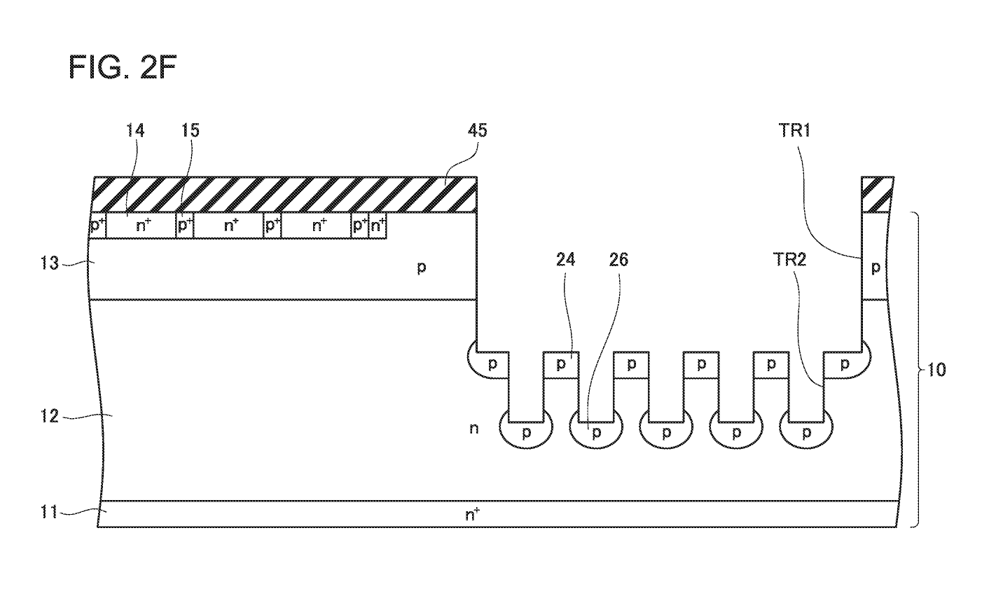

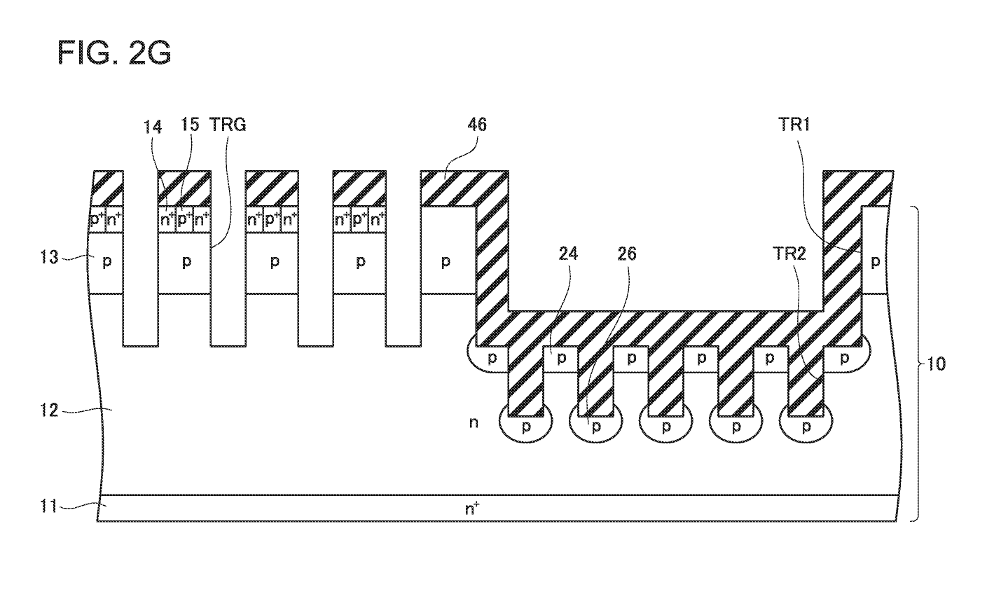

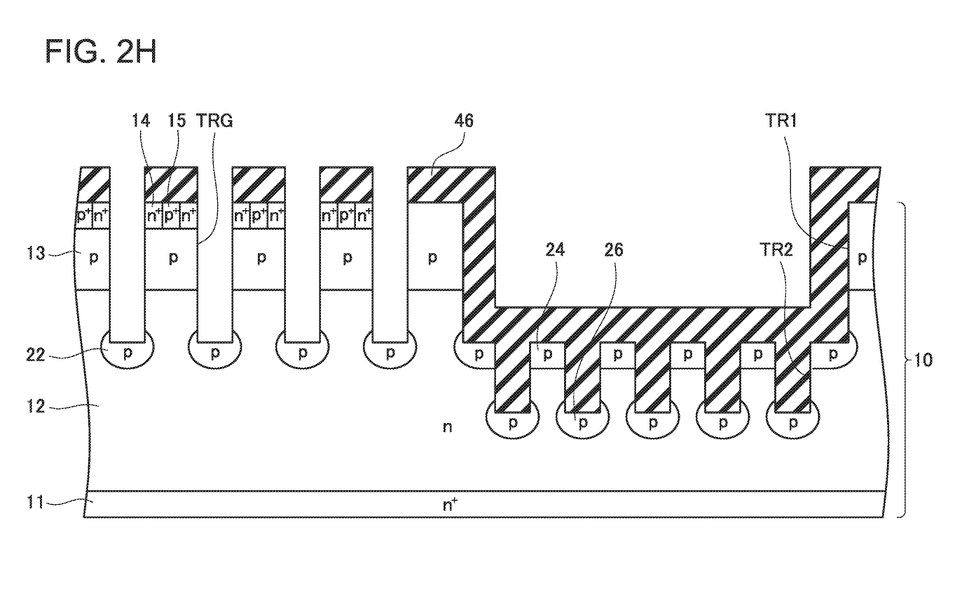

Next, a manufacturing method of the semiconductor device 1 will be described. As shown in FIG. 2A, the semiconductor substrate 10 is initially prepared. The drain region 11 and the body region 13 have been formed in the semiconductor substrate 10 by epitaxial growth, ion implantation, or the like.

Next, as shown in FIG. 2B, a mask 41 that has an opening is patterned on the upper surface of the semiconductor substrate 10. The opening of the mask 41 is formed at a position that corresponds to the peripheral portion 10B of the semiconductor substrate 10. Next, anisotropic etching is utilized to etch the semiconductor substrate 10 exposed from the opening of the mask 41, to form the first trench TR1. The mask 41 is removed after the first trench TR1 is formed.

Next, as shown in FIG. 2C, a mask 42 that has an opening is patterned on the upper surface of the semiconductor substrate 10. An ion implantation technology is utilized to implant aluminum into the upper surface of the semiconductor substrate 10 exposed from the opening of the mask 42, to form the body contact regions 15. The mask 42 is removed after the body contact regions 15 are formed.

Next, as shown in FIG. 2D, a mask 43 that has an opening is patterned on the upper surface of the semiconductor substrate 10. An ion implantation technology is utilized to implant phosphorus into the upper surface of the semiconductor substrate 10 exposed from the opening of the mask 43, to form the source regions 14. The mask 43 is removed after the source regions 14 are formed.

Next, as shown in FIG. 2E, a mask 44 that has an opening is patterned on the upper surface of the semiconductor substrate 10. The opening of the mask 44 is formed at a position at the bottom surface of the first trench TR1. Next, anisotropic etching is utilized to etch the semiconductor substrate 10 exposed from the opening of the mask 44, to form the second trenches TR2. The mask 44 is removed after the second trenches TR2 are formed.

Next, as shown in FIG. 2F, a mask 45 that has an opening is patterned on the upper surface of the semiconductor substrate 10. The opening of the mask 45 is formed at a position that corresponds to the peripheral portion 10B of the semiconductor substrate 10. Due to this, the first trench TR1 and the plurality of second trenches TR2 are exposed at the opening of the mask 45. Next, an ion implantation technology is utilized to implant aluminum or boron into the bottom surface of the first trench TR1 and the bottom surface of each of the plurality of second trenches TR2, exposed from the opening of the mask 45, to form the first floating regions 24 and the second floating regions 26. The mask 45 is removed after these floating regions 24 and 26 are formed.

Next, as shown in FIG. 2G, a mask 46 that has an opening is patterned on the upper surface of the semiconductor substrate 10. Anisotropic etching is utilized to etch the semiconductor substrate 10 exposed from the opening of the mask 46, to form the gate trenches TRG.

Next, as shown in FIG. 2H, an ion implantation technology is utilized, with the mask 46 being allowed to remain, to implant aluminum or boron into the bottom surface of the gate trench TRG to form the gate floating regions 22. The mask 46 is removed after the gate floating regions 22 are formed.

Next, a CVD technology is utilized to form the gate insulating film 8b and the gate electrode 8a in each of the gate trench TRG, to form the each trench gate 8 (see FIG. 1). At this time, the second trench TR2 can be ensured to have a trench width smaller than the trench width of the gate trench TRG, to thereby apply the gate insulating film 8b and form the protection film 32 simultaneously. Finally, the drain electrode 4 and the source electrode 6 are applied onto the lower surface and the upper surface of the semiconductor substrate 10, respectively, to complete the semiconductor device 1.

As shown in FIG. 2E, the mask 44 is utilized to form the second trenches TR2 hr the above-described manufacturing method. With the subsequent ion implantation, the first floating regions 24 are formed between the second trenches TR2, and the second floating region 26 is formed at the bottom surface of the corresponding second trench TR2. In other words, one mask 44 is utilized to determine the positions of the first floating regions 24 and the second floating regions 26. Accordingly, there occurs no relative positional deviation between the first floating regions 24 and the second floating regions 26, and hence fluctuations in withstand voltage due to manufacturing variations are restrained, and a yield of the semiconductor device 1 is improved.

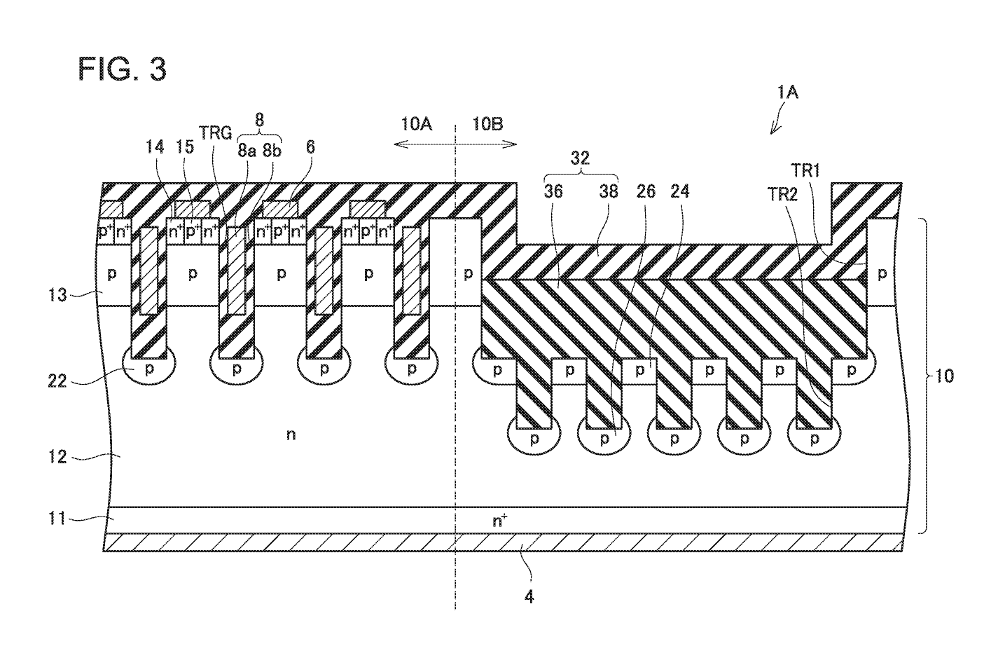

A semiconductor device 1A in a variation shown in FIG. 3 is characterized in that the protection film 32 comprises two types of insulators in the peripheral portion 10B. A lower protection film 36 fills the second trenches TR2. An upper protection film 38 coats the lower protection film 36. For example, as the lower protection film 36, the mask 46 shown in FIGS. 2G and 2H can be utilized. In other words, the mask 46 located in the peripheral portion 10B can be allowed to remain, to thereby be utilized as the lower protection film 36. In this case, the upper protection film 38 can be formed simultaneously with the step of forming the gate insulating film 8b of the trench gate 8, Notably, a material of the lower protection film 36 may be n-type silicon carbide (SiC) that has an impurity concentration equal to or lower than the impurity concentration of the drift region 12. In this case, the material of the semiconductor substrate 10 and the material of the lower protection film 36 are the same, and hence thermal stress in the second trench TR2, caused by the thermal expansion difference, is mitigated.

### Embodiment 2

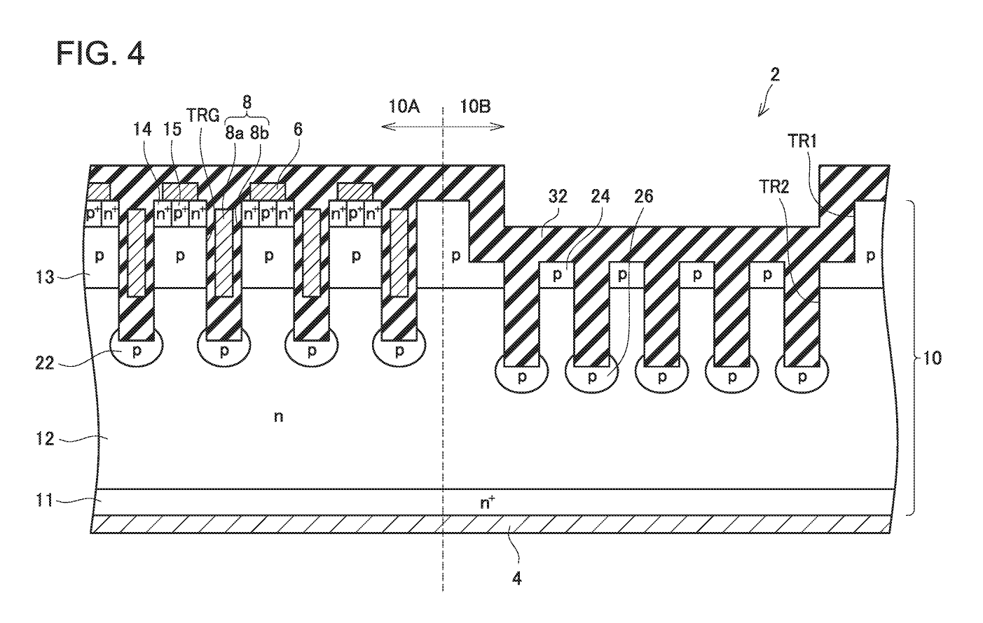

A semiconductor device 2 shown in FIG. 4 is characterized in that the first trench TR1 is shallower than the body region 13 in the element portion 10A. The semiconductor device 2 is characterized by its manufacturing method. A manufacturing method of the semiconductor device 2 will hereinafter be described.

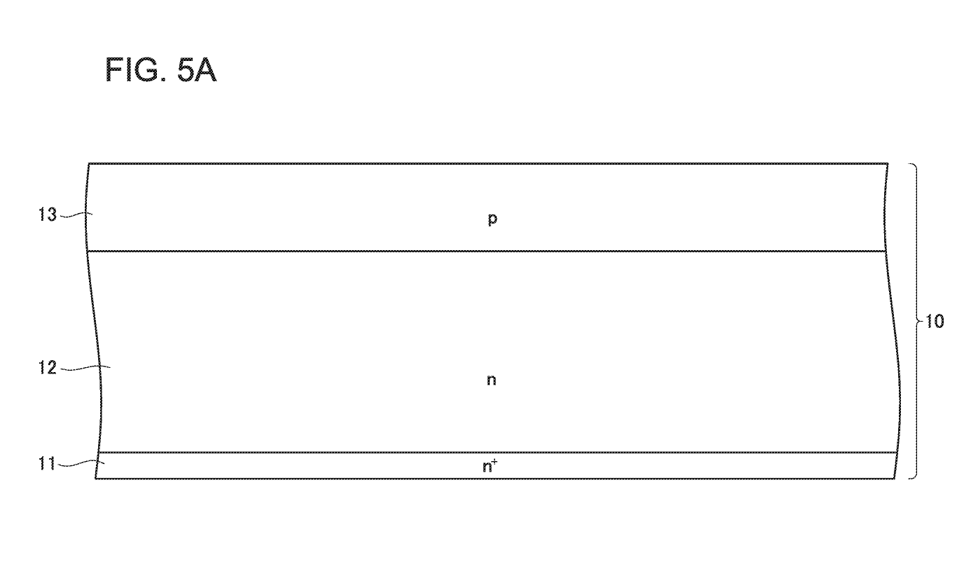

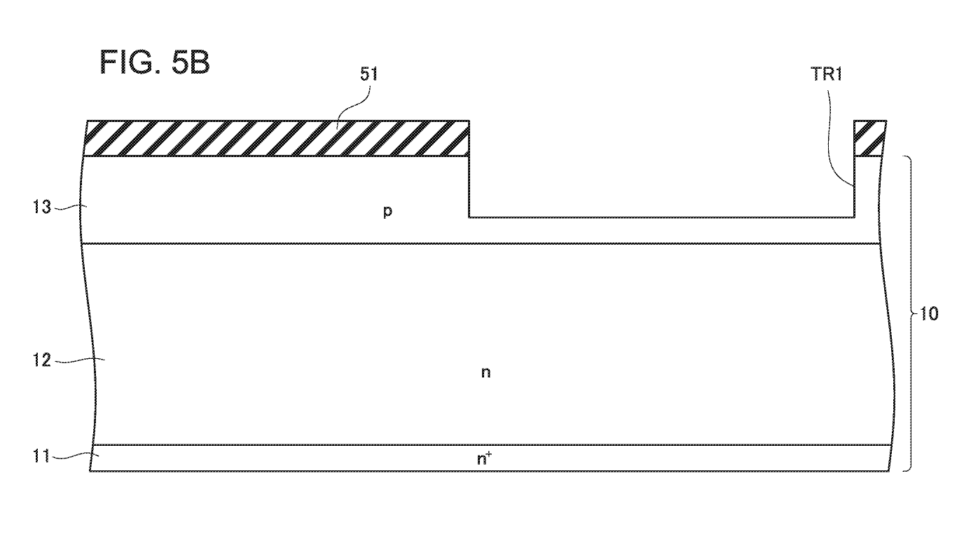

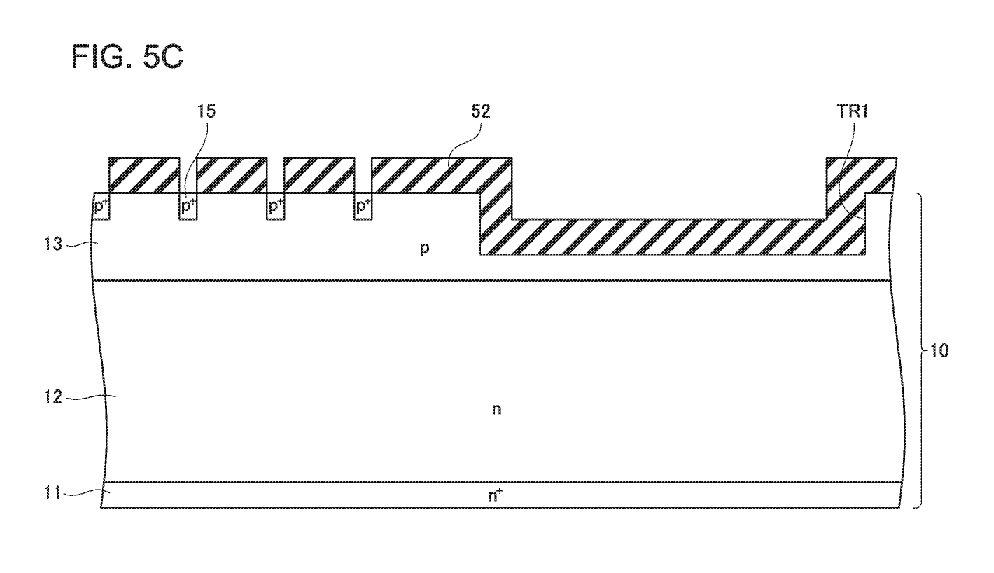

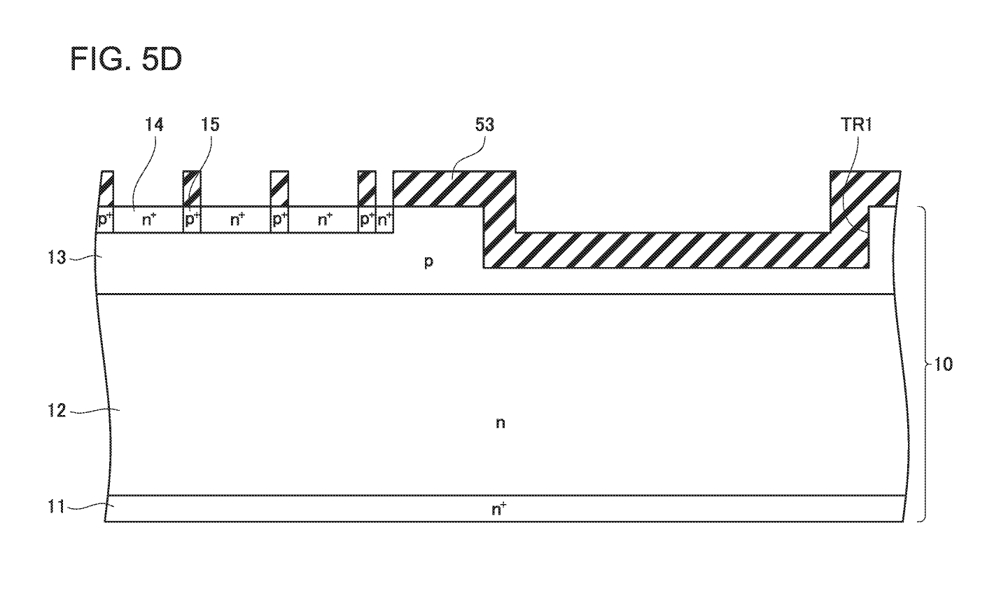

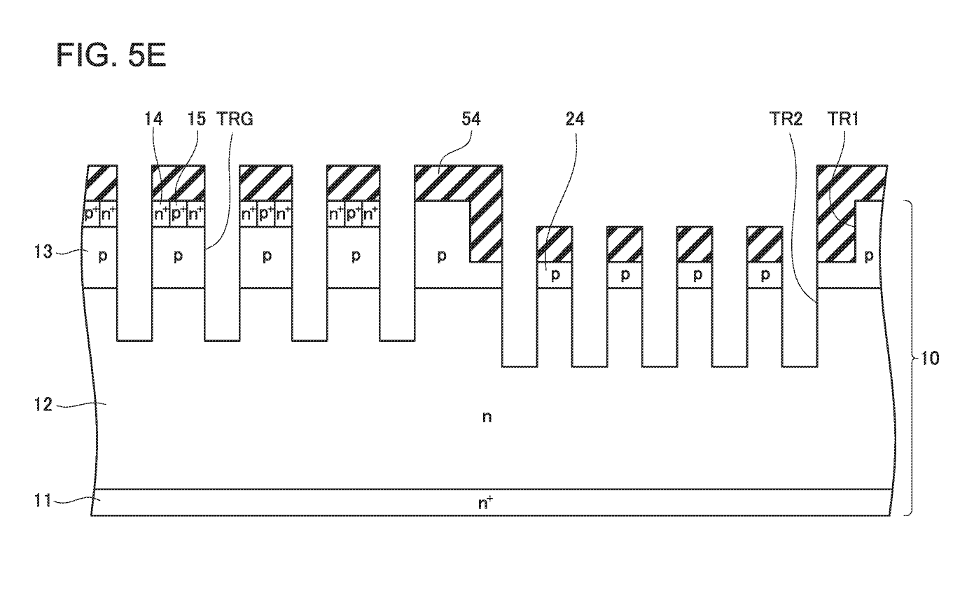

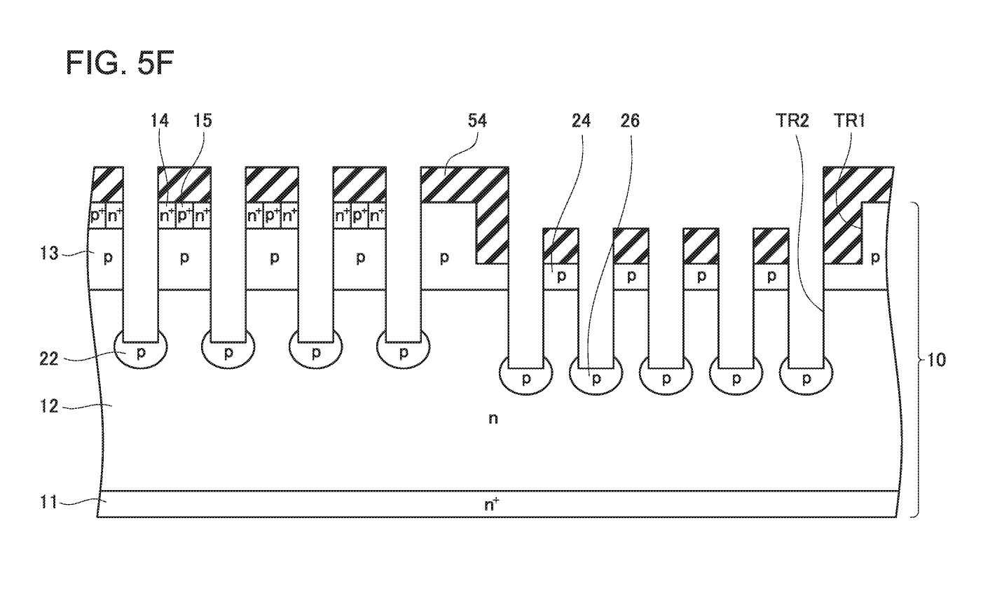

As shown in FIG. 5A, the semiconductor substrate 10 is initially prepared. The drain region 11 and the body region 13 are formed in the semiconductor substrate 10 by epitaxial growth, ion implantation, or the like. Notably, the drift region 12 in the semiconductor substrate 10 corresponds to claimed “first semiconductor layer”, and the body region 13 in the semiconductor substrate 10 corresponds to claimed “second semiconductor layer”.

Next, as shown in FIG. 5B, a mask 51 that has an opening is patterned on the upper surface of the semiconductor substrate 10. The opening of the mask 51 is formed at a position that corresponds to the peripheral portion 10B of the semiconductor substrate 10. Next, anisotropic etching is utilized to etch the semiconductor substrate 10 exposed from the opening of the mask 51, to form the first trench TR1. The first trench TR1 is formed to be shallower than the body region 13. The mask 51 is removed after the first trench TR1 is formed.

Next, as shown in FIG. 5C, a mask 52 that has an opening is patterned on the upper surface of the semiconductor substrate 10. An ion implantation technology is utilized to implant aluminum into the upper surface of the semiconductor substrate 10 exposed from the opening of the mask 52, to form the body contact regions 15. The mask 52 is removed after the body contact regions 15 are formed. p Next, as shown in FIG. 5D, a mask 53 that has an opening is patterned on the upper surface of the semiconductor substrate 10. An ion implantation technology is utilized to implant phosphorus into the upper surface of the semiconductor substrate 10 exposed from the opening of the mask 53, to form the source regions 14. The mask 53 is removed after the source regions 14 are formed.

Next, as shown in FIG. 5E, a mask 54 that has an opening is patterned on the upper surface of the semiconductor substrate 10. The opening of the mask 54 is formed at a position at the bottom surface of the first trench TR1, and at a part of the element portion 10A of the semiconductor substrate 10. Next, anisotropic etching is utilized to etch the semiconductor substrate 10 exposed from the opening of the mask 54, to form the second trenches TR2 and the gate trench TRG. At this time, the body region 13 that exists below the first trench TR1 is divided into a plurality of sections by the second trenches TR2, and turns into the first floating regions 24. The mask 54 is removed after the second trenches TR2 and the gate trenches TRG are formed.

Next, as shown in FIG. 5F, an ion implantation technology is utilized, with the mask 54 being allowed to remain, to implant aluminum or boron into the bottom surface of the second trenches TR2 and the bottom surface of the gate wenches TRG, to form the second floating regions 26 and the gate floating regions 22. The mask 54 is removed after the second floating regions 26 and the gate floating regions 22 are formed.

Next, a CVD technology is utilized to form the gate insulating film 8b and the gate electrode 8a in each gate trench TRG, to form the trench gate 8 (see FIG. 4). At this time, the second trenches TR2 can be ensured to have a trench width smaller than the trench width of the gate trench TRG, to thereby apply the gate insulating film 8b and form the protective film 32 simultaneously. Finally, the drain electrode 4 and the source electrode 6 are applied onto the lower surface and the upper surface of the semiconductor substrate 10, respectively, to complete the semiconductor device 2.

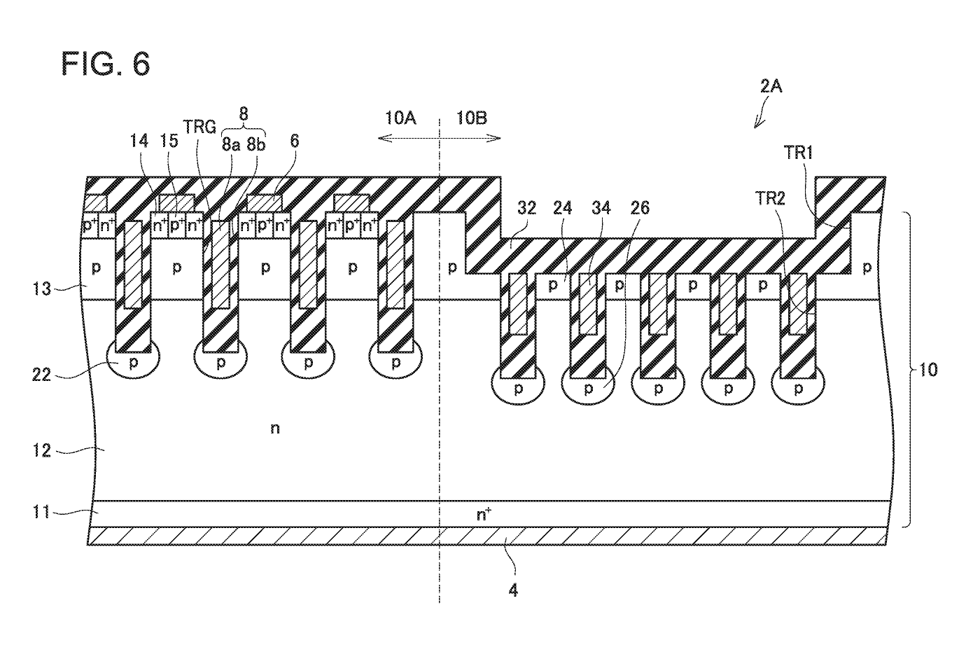

A semiconductor device 2A in a variation shown in FIG. 6 is characterized in that it further includes a filling electrode 34 disposed in each second trench TR2. Each of the filling electrode 34 is covered with the protective film 32. The filling electrode 34 may have a floating potential, or a source potential. If the filling, electrode 34 has a floating potential, depletion in the peripheral portion 10B when the semiconductor device 1 is turned off is promoted by an effect of capacitive coupling between the filling electrodes 34. If the filling electrode 34 has a source potential, depletion in the peripheral portion 10B when the semiconductor device 1 is turned off is promoted by a field plate effect. Notably, the second trench TR2 can be ensured to have the same trench width as the trench width of the gate trench TRG, to thereby form the protective film 32 and the fang electrode 34 simultaneously with the step of forming the trench gate 8 in the gate trench TRG.

Some of the features characteristic to above-described embodiments will herein be listed. It should be noted that the respective technical elements are independent of one another, and are useful solely or in combinations. The combinations thereof are not limited to those described in the claims as originally filed.

An example of the semiconductor device disclosed herein includes a MOSFET or an IGBT. The semiconductor device comprises a semiconductor substrate partitioned into an element portion provided with a switching structure and a peripheral portion provided with a terminal structure. A material of the semiconductor substrate is not particularly limited, but an example thereof includes silicon, silicon carbide, or a nitride semiconductor. As an example of the switching structure, a MOS structure is provided. The terminal structure may include a first trench, a plurality of second trenches, a plurality of first floating regions and a plurality of second floating regions. The first trench extends along a depth direction from one of main surfaces of the semiconductor substrate. Each of the plurality of second trenches extends along the depth direction from a bottom surface of the first trench, and the second trenches are arranged at intervals in a direction away from the element portion. The plurality of first floating regions has a floating potential. Each of the first floating regions is disposed at the bottom surface of the first trench, is arranged between the second trenches, and forms a PN-junction with a surrounding region thereof. The plurality of second floating regions has a floating potential. Each of the second floating regions is disposed at a bottom surface of the second trench and forms a PN-junction with a surrounding region thereof. Each of second floating regions is arranged to be separated from each other in the direction away from the element portion.

The first floating region and the second floating region may be arranged to be separated from each other in the depth direction.

In a view along the direction orthogonal to the one of main surfaces of the semiconductor substrate, a part of each of the second floating regions may be arranged to overlap the first floating region. According to this aspect, extension of the depletion layer in the peripheral portion is promoted, and the withstand voltage of the semiconductor device is improved.

A manufacturing method disclosed herein is the manufacturing method of a semiconductor device comprising a semiconductor substrate partitioned into an element portion provided with a switching structure and a peripheral portion provided with a terminal structure. The method comprise preparing the semiconductor substrate, forming a first trench, forming a plurality of second trenches, forming a plurality of first floating regions and forming a plurality of second floating regions. In the forming of the first trench, the first trench extending along a depth direction from one of main surfaces of the semiconductor substrate at the peripheral portion is formed. In the forming of the plurality of second trenches, each of second trenches extending along the depth direction from a bottom surface of the first trench is formed such that second trenches are arranged at intervals in a direction away from the element portion. In the forming of the plurality of first floating regions, the plurality of first floating regions having a floating potential is formed such that each of first floating regions is disposed at the bottom surface of the first trench, is arranged between the second trenches, and forms PN-junction with a surrounding region thereof. In the forming of the plurality of second floating regions, the plurality of second floating regions having a floating potential is formed such that each of the second floating regions is disposed at a bottom surface of the second trench and forms a PN-junction with a surrounding region thereof. Each of second floating regions is arranged to be separated from each other in the direction away from the element portion.

In one example of the above manufacturing method, the forming of the plurality of first floating regions and the forming of the plurality of second floating regions may be performed at the same time. In this case, in the forming of the plurality of first floating regions and the forming of the plurality of second floating regions, ions are implanted toward bottom surfaces of the first and second trenches in a state where the first and second trenches are exposed.

In the other example of the above manufacturing method, the forming of the plurality of first floating regions and the forming of the plurality of second floating regions may be performed at the same time. In this case, in the preparing of the semiconductor substrate, the semiconductor substrate is prepared to include at the peripheral portion a configuration in that a first semiconductor layer of a first conductivity type and a second semiconductor layer of a second conductivity type are laminated, the second semiconductor layer being exposed at one main surfaces of the semiconductor substrate. In the forming of the first trench, the first trench which is shallower than the second semiconductor layer is formed. In the firming of the plurality of first floating regions and the forming of the plurality of second floating regions, the plurality of second trenches extending along the depth direction from the bottom surface of the first trench are formed.

Specific examples of the present teachings has been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

What is claimed is:

1. A semiconductor device comprising:
a semiconductor substrate partitioned into an element portion provided with a switching structure and a peripheral portion provided with a terminal structure,
wherein the terminal structure includes:
a first trench extending along a depth direction from one of main surfaces of the semiconductor substrate;
a plurality of second trenches, wherein each of the second trenches extends along the depth direction from a bottom surface of the first trench, and the second trenches are arranged at intervals in a direction away from the element portion;
a plurality of first floating regions having a floating potential, wherein each of the first floating regions is disposed at the bottom surface of the first trench, is arranged between the second trenches, and forms a PN-junction with a surrounding region thereof; and
a plurality of second floating regions having a floating potential, wherein each of the second floating regions is disposed at a bottom surface of the second trench and forms a PN-junction with a surrounding region thereof, and
the second floating regions are arranged to be separated from each other in the direction away from the element portion.

2. The semiconductor device according to claim 1, wherein
the first floating region and the second floating region are arranged to be separated from each other in the depth direction.

3. The semiconductor device according to claim 1, wherein
in a view along a direction orthogonal to the one of main surfaces of the semiconductor substrate, a part of each of the second floating regions is arranged to overlap the first floating region.

4. A manufacturing method of a semiconductor device comprising a semiconductor substrate partitioned into an element portion provided with a switching structure and a peripheral portion provided with a terminal structure, the method comprising:
preparing the semiconductor substrate;
forming a first trench extending along a depth direction from one of main surfaces of the semiconductor substrate at the peripheral portion;
forming a plurality of second trenches, wherein each of second trenches extends along the depth direction from a bottom surface of the first trench and second trenches are arranged at intervals in a direction away from the element portion;
forming a plurality of first floating regions having a floating potential, wherein each of first floating regions is disposed at the bottom surface of the first trench, is arranged between the second trenches, and forms PN-junction with a surrounding region thereof; and
forming a plurality of second floating regions having a floating potential, wherein each of the second floating regions is disposed at a bottom surface of the second trench and forms a PN-junction with a surrounding region thereof, and
the second floating regions are arranged to be separated from each other in the direction away from the element portion.

5. The manufacturing method according to claim 4, wherein
the forming of the plurality of first floating regions and the forming of the plurality of second floating regions are performed at the same time by implanting ions toward bottom surfaces of the first and second trenches in a state where the first and second trenches are exposed.

6. The manufacturing method according to claim 4, wherein
in the preparing of the semiconductor substrate, the semiconductor substrate is prepared to include at the peripheral portion a configuration in that a first semiconductor layer of a first conductivity type and a second semiconductor layer of a second conductivity type are laminated, the second semiconductor layer being exposed at the one of main surfaces of the semiconductor substrate,
in the forming of the first trench, the first trench which is shallower than the second semiconductor layer is formed, and
the forming of the plurality of second trenches and the forming of the plurality of first floating regions are performed at the same time by forming the plurality of second trenches extending along the depth direction from the bottom surface of the first trench.
